(19) United States
(12) Patent Application Publication
(10) Pub. No.: US 2026/0214820 A1
(43) Pub. Date: Jul. 23, 2026

(54) Slidable Display Apparatus

(71) Applicant: LG Display Co., Ltd., Seoul (KR)

(72) Inventor: Sung-Sik Son, Paju-si (KR)

(21) Appl. No.: 19/385,667

(22) Filed: Nov. 11, 2025

(30) Foreign Application Priority Data
Dec. 20, 2024 (KR) 10-2024-0192120

(51) Int. Cl. H05K 5/02

(52) U.S. Cl. CPC H05K 5/0217

(57) ABSTRACT

A display apparatus presented herein includes a display panel including a first region where an image is displayed, a second region, and a third region, wherein the first region is deformable, and wherein the second and third regions are positioned outside the first region and are not deformable. The display apparatus further includes a support member that supports the display panel, and an adhesive member that attaches the support member to the display panel. The adhesive member includes a first adhesive member corresponding to the first region of the display panel, a second adhesive member corresponding to the second region of the display panel, and a third adhesive member corresponding to the third region of the display panel. A modulus of the first adhesive member is smaller than a modulus of the second adhesive member and a modulus of the third adhesive member.

### CROSS-REFERENCE TO RELATED APPLICATION

The present application claims priority to Republic of Korea Patent Application No. 10-2024-0192120 filed on Dec. 20, 2024, which is hereby incorporated by reference in its entirety.

### BACKGROUND

### Field

The present disclosure relates to a slidable display apparatus capable of preventing a support member from being peeled off from a display panel.

### Discussion of Related Art

Recently, with development of multimedia, importance of display apparatuses is increasing. In response to this, flat panel display apparatuses such as liquid crystal display apparatuses, and organic electroluminescent display apparatuses are being commercialized. Among these display apparatuses, organic electroluminescent display apparatuses are currently widely used because they have high response speed, high brightness, and good viewing angle.

Additionally, various flexible display apparatuses have been developed recently. For example, rollable, stretchable, and slidable display apparatuses are being developed. However, these display apparatuses have a support member attached to a display panel to support the display panel. However, due to difference in stress between regions, there is a problem with the support member being peeled off from the display panel.

### SUMMARY

An advantage of the present disclosure is to provide a display apparatus that can prevent a support member from being peeled off from a display panel by setting modulus of an adhesive member differently among regions.

Additional features and advantages of the present disclosure will be set forth in the description which follows, and in part will be apparent from the description, or may be learned by practice of the present disclosure. These and other advantages of the present disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes a display panel including a first region where an image is displayed and deformable, and a second region and a third region that are positioned outside the first region and are not deformable; a support member that supports the display panel; and an adhesive member that attaches the support member to the display panel, wherein the adhesive member includes a first adhesive member corresponding to the first region of the display panel, and a second adhesive member and a third adhesive member corresponding to the second region and the third region of the display panel, respectively, and wherein a modulus of the first adhesive member is smaller than a modulus of the second adhesive member and a modulus of the third adhesive member.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the present disclosure and together with the description serve to explain the principles of the present disclosure. In the drawings:

FIG. 1 is a perspective view illustrating a display apparatus according to one or more embodiments of the present disclosure.

FIGS. 2A and 2B are side views of a display apparatus according to one or more embodiments of the present disclosure.

FIG. 3 is a cross-sectional view schematically illustrating a display module of a display apparatus according to one or more embodiments of the present disclosure.

FIG. 4 is a view illustrating a display panel according to one or more embodiments of the present disclosure.

FIG. 5 is a plan view of a support member according to one or more embodiments of the present disclosure.

FIG. 6 is a view enlarging a part of a support member according to one or more embodiments of the present disclosure.

FIG. 7 is a view illustrating a support member wound around a guide member according to one or more embodiments of the present disclosure.

FIG. 8 is a plan view of an adhesive member of a display apparatus according to one or more embodiments of the present disclosure.

FIG. 9A is a cross-sectional view of a first adhesive member according to one or more embodiments of the present disclosure.

FIG. 9B is a cross-sectional view of second and third adhesive members according to one or more embodiments of the present disclosure.

FIGS. 10A and 10B are views illustrating other shapes of a sawtooth shape of an adhesive member according to one or more embodiments of the present disclosure.

FIG. 11 is a view illustrating another structure of an adhesive member according to one or more embodiments of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure can be defined by the scope of the claims.

The shapes, sizes, dimensions (e.g., length, width, height, thickness, radius, diameter, area, etc.), proportions, angles, numbers, and the like disclosed in the drawings for explaining the embodiments of the present disclosure are illustrative, and the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout the description. Furthermore, in describing the present disclosure, if it is determined that a detailed description of the related known technology unnecessarily obscure the subject matter of the present disclosure, the detailed description thereof can be omitted. When terms such as “include,” “have,” “comprise,” “constitute,” “make up of,” “formed of,” and “consist of”, and the like are used in this disclosure, other parts can be added unless ‘only’ is used. When a component is expressed in the singular, cases including the plural are included unless specific statement is described.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In interpreting the components, even if there is no separate explicit description, it is interpreted as including a margin range.

Where positional relationships are described, for example, where the positional relationship between two parts is described using “on,” “over,” “under,” “above,” “below,” “beneath,” “near,” “close to,” or “adjacent to,” “beside,” “next,” or the like, one or more other parts may be located between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In the case of a description of a temporal relationship, for example, when a temporal precedence is described as ‘after’, ‘following’, ‘before’, and the like, cases that are not continuous can be included unless ‘directly’ or ‘immediately’ is used.

Respective features of various embodiments of the present disclosure can be partially or wholly connected to or combined with each other and can be technically interlocked and driven variously, and respective embodiments can be independently implemented from each other or can be implemented together with a related relationship.

In describing components of the present disclosure, terms such as first, second, A, B, (a), (b) and the like can be used. These terms are only for distinguishing the components from other components, and an essence, sequence, order, or number of the components is not limited by the terms. Further, when it is described that a component is “connected”, “coupled” or “contact” to another component, the component can be directly connected or contact the another component, but it should be understood that other component can be “interposed” between the components, or the components can be “connected”, “coupled” or “contact” through other component.

The term “at least one” should be understood to include all combinations of one or more of related elements. For example, the term of “at least one of first, second and third elements” may include all combinations of two or more of the first, second and third elements as well as the first, second or third element.

In this disclosure, a “display apparatus” can include a narrowly defined display apparatus, such as a display module or the like, including a display panel and a driving portion for driving the display panel. Furthermore, the “display apparatus” can include a complete product or final product which is a notebook computer, a television, a computer monitor, an automotive device or equipment display including other type of vehicle, or a set electronic device or set device or set apparatus such as a mobile electronic device which is a smart phone, an electronic pad or the like, including the display module or the like.

Therefore, the display apparatus of this disclosure can include a narrowly defined display apparatus itself such as the display module or the like, and/or an application product or a set device that is an end-user device, including the display module or the like.

Hereinafter, embodiments of the present disclosure are described in detail with reference to the drawings.

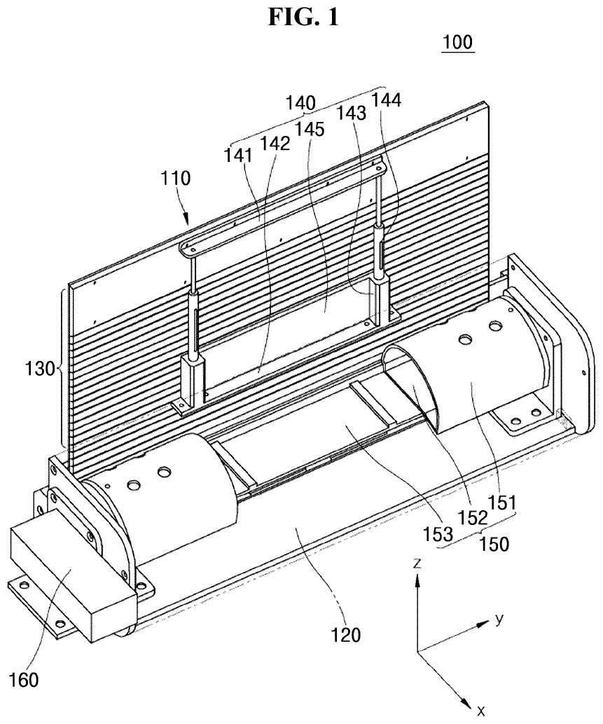

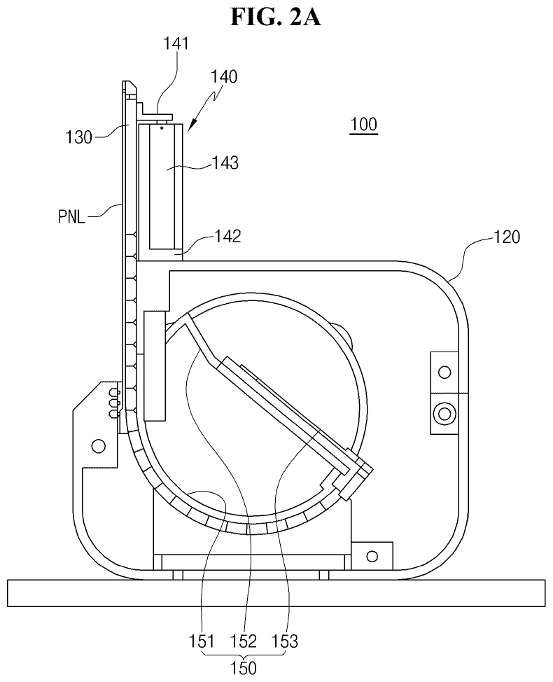

FIG. 1 is a perspective view illustrating a display apparatus according to one or more embodiments of the present disclosure. FIGS. 2A and 2B are side views of a display apparatus according to one or more embodiments of the present disclosure.

Referring to FIGS. 1, 2A, and 2B, the display apparatus 100 according to one or more embodiments of the present disclosure can include a display module 110, a housing 120 in which the display module 110 is accommodated, a guide member 150 that guides the display module 110 into the housing 120, and a motor 160 that drives the display module 110 into the housing 120.

The housing 120 can include at least a portion of the display module 110. For example, the housing 120 can be embedded in a dashboard of a vehicle to store the display module 110 within the dashboard. However, the present disclosure is not limited to this structure. For example, the display module 110 can be entirely housed in the housing 120, or a portion of the display module 110 can be exposed outside the housing 120 and another portion of the display module 110 can be housed within the housing 120.

The display module 110 can includes a display panel PNL displaying an image, and a support member 130 disposed on one side or both sides of the display panel PNL to support the display panel PNL. The display panel PNL can be formed of a flexible material, such as plastic, such that at least a portion thereof is deformable.

The support member 130 can support and guide the display panel PNL so that the display panel PNL can slide, bend, or roll in one direction. For example, the support member 130 can be an apron.

The support member 130 can serve to reinforce rigidity of the display panel PNL and to prevent the display panel PNL from bending in an undesirable direction. The support member 130 can be formed of a metal such as aluminum (Al), magnesium (Mg), or stainless steel (SUS), but not limited thereto.

The support member 130 can be described in more detail later.

A moving member 140 can be disposed on a rear surface of the support member 130. One end of the moving member 140 can be mounted to the support member 130, and the other end of the moving member 140 can be mounted to the housing 120. The moving member 140 can include a connecting portion 141, a frame 142, a moving support 143, a moving portion 144, and a reinforcing plate 145.

The connecting portion 141 can be coupled to the support member 130 and can move together with the support member 130 when the support member 130 moves. The connecting portion 141 can be formed in a bar shape and can be coupled to the upper rear surface of the support member 130. The connecting portion 141 can be provided to be raised and lowered from the housing 120. As the connecting portion 141 is raised and lowered, the support member 130 coupled to the connecting portion 141, i.e., the display module 110 can also be raised and lowered. The connecting portion 141 can connects the support member 130 and the moving portion 144.

The frame 142 can be coupled to the housing 120. The frame 142 can be configured in a bar shape and can be coupled to the housing 120. The housing 120 can support the frame 142.

The moving support 143 can be formed to protrude upward from the frame 142. The moving support 143 can be provided as a pair, and each of the pair of moving supports 143 can be spaced apart from each other by a certain distance in a horizontal direction (e.g., y direction). A hollow portion in which the moving portion 144 is mounted can be formed in the moving support 143.

The reinforcing plate 145 can be positioned between the pair of moving supports 143 spaced apart from each other, and can be coupled with the moving support 143 to allow the pair of moving supports 143 to maintain the set distance apart from each other. The reinforcing plate 145 can be formed in a plate shape, but not limited thereto. The reinforcing plate 145 can be manufactured integrally with the pair of moving supports 143 or can be omitted as needed. In addition, the frame 142, the moving support 143, and the reinforcing plate 145 can be manufactured integrally.

The moving portion 144 can be coupled at one end thereof to the connecting portion 141, and can be inserted into the moving support 143 to move in a z-direction with respect to the moving support 143. The moving portion 144 can be inserted into the hollow portion of the moving support 143 and can move up and down from the moving support 143. The moving portion 144 can support the support member 130 so that when the display module 110 is raised from the housing 120, the exposed portion of the display module 110 can maintain linearity.

The housing 120 can be configured to accommodate at least a portion of the display module 110. When the display module 110 slides down, at least a portion of the display module 110 can be bent and then rolled into a cylindrical shape to be accommodated in the housing 120.

The guide member 150 can be a rolling guide. The guide member 150 can be installed in the housing 120 and, as it rolls, the display module 110 can be wound around an outer surface of the guide member 150 and accommodated within the housing 120. The guide member 150 can be formed of a metal such as aluminum (Al), magnesium (Mg), or stainless steel (SUS), but not limited thereto.

The guide member 150 can include a curved portion 151, a connecting portion 152, and a bridge 153. The display module 110 can be wound around the outer surface of the curved portion 151. The curved portion 151 can be formed in a cylindrical or semi-cylindrical shape, but not limited thereto.

A pair of curved portions 151 can be provided on both sides of the rear surface of the display module 110, and each of the pair of curved portions 151 can be spaced apart from each other in the second direction of the display module 110. The bridge 153 can be positioned between the pair of curved portions 151.

One end of the display module 110 can be fixed to the guide member 150. For example, one end of the display module 110 can be fixed to the curved portion 151 of the guide member 150, but not limited thereto.

The motor 160 can be positioned on one side of the guide member 150 to elevate the display module 110. In other words, the moving portion 144 can be elevated by the operation of the motor 160, and as the moving portion 144 can move upward, the display module 110 can move up and be ejected from the housing 120. The motor 160 can be coupled to the housing 120, and a rotation shaft can be coupled to the guide member 150. Thus, when the motor 160 rotates, the guide member 150 can rotate, and accordingly, the display module 110 can be wound around the guide member 150 or be released from the guide member 150, and the display module 110 can be raised and lowered.

Hereinafter, a sliding operation method of the slidable display apparatus 100 according to the present disclosure can be described with reference to FIGS. 2A and 2B.

FIG. 2A is a view illustrating a state in which the display module 110 is housed inside the housing 120, and FIG. 2B is a view illustrating a state in which the display module 110 is ejected from the housing 120.

As illustrated in FIG. 2A, one end of the display module 110 can be fixed to the curved portion 151 of the guide member 150, and the other end of the display module 110 can be placed outside the housing 120 or fixed inside an inlet of a discharge port of the housing 120. At this time, the display apparatus 100 can be in an off state, so that the bendable or flexible display module 110 can be accommodated inside the housing 120 in a state of being wound around the curved portion 151 of the guide member 150.

As illustrated in FIG. 2B, when the display apparatus 100 is turned on, the motor 160 can be driven, and as the motor 160 is driven, the guide member 150 connected to a driving shaft of the motor 160 can begin to rotate counterclockwise.

As the guide member 150 rotates, the moving portion 144 inserted into the hollow portion of the moving support 143 can begin to rise in the z-direction. As the moving portion 144 rises, the display module 110 coupled to the moving portion 144 through the connecting portion 141 can rise, and the display module 110 wound around the guide member 150 can be released from the guide member 150 and discharged to the outside of the housing 120 through the outlet of the housing 120. At this time, since the display module 110 is equipped with the support member 130, the display module 110 completely ejected from the housing 120 can display an image while maintaining a flat state.

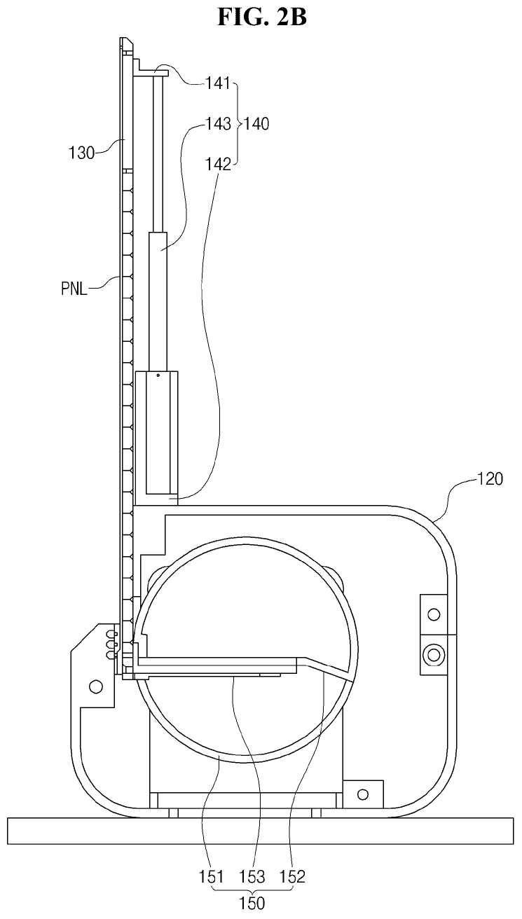

FIG. 3 is a cross-sectional view schematically illustrating a display module of a display apparatus according to one or more embodiments of the present disclosure.

As illustrated in FIG. 3, the display module 110 can include the display panel PNL displaying an image, the support member 130 below the display panel PNL, and an adhesive member 180 that attaches the support member 130 to the display panel PNL.

The display panel PNL can be any one of various display panels. For example, the display panel PNL can be an organic electroluminescent display panel, a liquid crystal display panel, an electrophoretic display panel, a micro LED display panel, a mini LED display panel, etc. The display panel PNL can be a flexible display panel capable of bending or flexing.

The support member 130 can be formed of a metal such as aluminum (Al), magnesium (Mg), or stainless steel (SUS), but not limited thereto. The support member 130 can support the display panel PNL and ensure that the display module 110 remains flat and perpendicular to a ground when the display module 110 rises and exits the housing 120.

A chamfer 132 can be formed at a set interval at a lower surface (or rear surface) of the support member 130, i.e., a surface not attached to the display panel PNL. The chamfer 132 can provide a bending property to the support member 130 made of metal, allowing the display panel PNL to be easily wound around the guide member 150 in a cylindrical shape.

The adhesive member 180 can be a double-sided tape. As described in detail later, the adhesive member 180 can configured with a plurality of regions with different elasticities, which can prevent poor adhesion between the display panel PNL and the support member 130 that is caused due to the adhesive member 180 being peeled off due to stress. This can be described in more detail later.

A back plate can be disposed below the display panel PNL, and a polarizing plate and a cover window can be disposed on the display panel PNL.

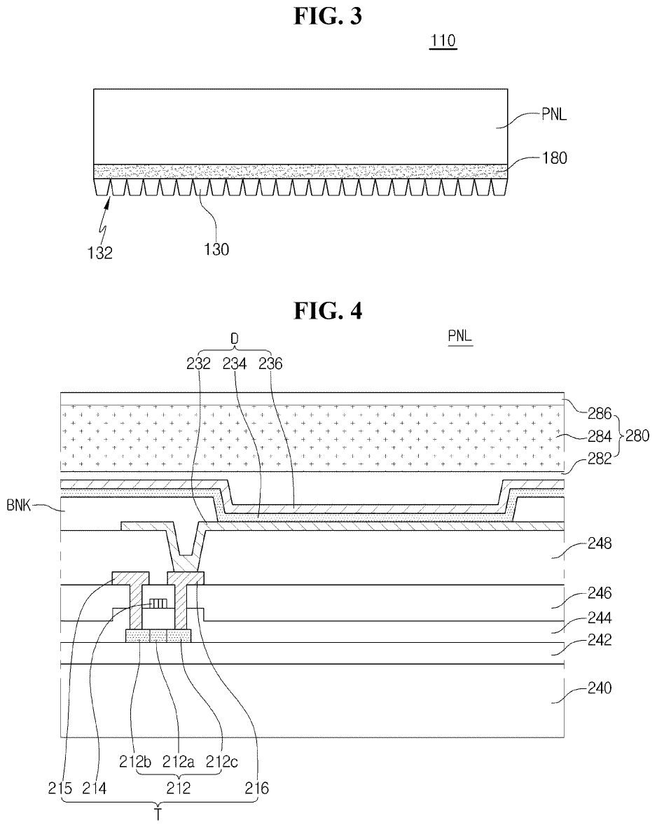

FIG. 4 is a view illustrating a display panel of FIG. 3. The display panel PNL according to one or more embodiments of present disclosure can use any one of various display panels, but an organic electroluminescent display panel can be described below as an example.

As illustrated in FIG. 4, a buffer layer 242 can be formed on a substrate 240. The substrate 240 can be formed of a plastic material such as polyimide, polymethylmethacrylate, polyethylene terephthalate, polyethersulfone, or polycarbonate, but not limited thereto.

For example, when the substrate 240 is formed of polyimide, it can be configured with multiple layers made of polyimide, and an inorganic layer can be further disposed between the layers of polyimide, but not limited thereto.

The buffer layer 242 can serve to improve adhesion between layers formed thereon and the substrate 240, and to block various types of defects, such as alkaline components leaking from the substrate 240. Furthermore, the buffer layer 242 can serve to delay diffusion of moisture or oxygen that penetrates the substrate 240.

The buffer layer 242 can be formed as a single layer of SiNx or SiOx, or as multiple layers using SiNx and/or SiOx. When the buffer layer 242 is formed with multiple layers, SiOx and SiNx can be formed alternately. The buffer layer 242 can be omitted depending on type and material of the substrate 240, structure and type of a thin film transistor, etc.

A thin film transistor T can be formed on the buffer layer 242. For convenience of explanation, a driving thin film transistor among various thin film transistors that can be arranged in the display apparatus 100 is illustrated, but other thin film transistors including a switching thin film transistor can also be included in the display apparatus 100. Furthermore, while the drawing illustrates the thin film transistor T having a top gate structure, it is not limited to this structure and can be implemented with other structure, such as a bottom gate structure.

The thin film transistor T can include a semiconductor layer 212 positioned on the buffer layer 242, a gate insulating layer 244 formed on the semiconductor layer 212, a gate electrode 214 positioned on the gate insulating layer 244, an interlayered insulating layer 246 formed on the gate electrode 214, and a source electrode 215 and a drain electrode 216 positioned on the interlayered insulating layer 246.

The semiconductor layer 212 can be formed of a polycrystalline semiconductor. For example, the polycrystalline semiconductor can be formed of low-temperature polysilicon LTPS having high mobility, but not limited thereto.

Alternatively, the semiconductor layer 212 can be formed of an oxide semiconductor. For example, the semiconductor layer 212 can be formed of any one of IGZO (Indium-gallium-zinc-oxide), IZO (Indium-zinc-oxide), IGTO (Indium-gallium-tin-oxide), and IGO (Indium-gallium-oxide), but not limited thereto. The semiconductor layer 212 can be configured to include a channel region 212a in a central region, and a source region 212b and a drain region 212c which are doping regions on both sides.

The gate insulating layer 244 can be formed in a single layer or multiple layers using an inorganic material, such as SiOx and/or SiNx, but not limited thereto.

The gate electrode 214 can be formed of a metal. For example, the gate electrode 113 can be formed in a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto.

The interlayered insulating layer 246 can be formed in a single layer or multiple layers using an organic material, such as photoacrylic, or an inorganic material, such as SiNx and/or SiOx. Furthermore, the interlayered insulating layer 246 can be formed in multiple layers using an organic layer and an inorganic layer, but not limited thereto.

The source electrode 215 and the drain electrode 216 can be formed in a single layer or multiple layers using at least one of molybdenum (Mo), aluminum (Al), chromium (Cr), gold (Au), titanium (Ti), nickel (Ni), neodymium (Nd), copper (Cu), and an alloy thereof, but not limited thereto. The source electrode 215 and the drain electrode 216 can contact the source region 212b and the drain region 212c of the semiconductor layer 212 through contact holes formed in the gate insulating layer 244 and the interlayered insulating layer 246, respectively.

A bottom shield metal layer can be disposed below the semiconductor layer 212 and on the substrate 240. The bottom shield metal layer can minimize or at least reduce a backchannel phenomenon caused by charges trapped in the substrate 240 to prevent afterimages or performance degradation of the thin film transistor T. The bottom shield metal layer can be formed in a single layer or multiple layers using at least one of titanium (Ti), molybdenum (Mo), or an alloy thereof, but not limited thereto.

A planarization layer 248 can be formed on the substrate 240 on which the thin film transistor T is disposed. The planarization layer 248 can be formed of an organic material, such as photoacrylic, but not limited thereto and can also be formed in multiple layers including an inorganic layer and an organic layer.

An organic light emitting element (or organic light emitting diode) D can be disposed on the planarization layer 248. The organic light emitting element D can include a first electrode 232, a light emitting layer 234, and a second electrode 236, so that light emitted from the light emitting layer 234 can be output downward through the first electrode 232.

The first electrode 232 can be formed in a single layer or multiple layers using a metal, such as Ca, Ba, Mg, Al, Ag, and an alloy thereof.

A bank layer BNK can be formed at a boundary of each subpixel on the planarization layer 248. The bank layer BNK can be a type of partition wall defining the subpixel. The bank layer BNK can partition each subpixel, and prevent light of a specific color output from adjacent pixel from being mixed and output.

The bank layer BNK can be formed of at least one of an inorganic insulating material such as SiNx or SiOx, an organic insulating material such as BCB (BenzoCycloButene), an acrylic resin, an epoxy resin, a phenolic resin, a polyamide resin, or a polyimide resin, and a photosensitive agent including a black pigment, but not limited thereto.

The light emitting layer 234 can include a red (R) light emitting layer that is formed in a red subpixel and emits red light, a green (G) light emitting layer that is formed in a green subpixel and emits green light, and a blue (B) light emitting layer that is formed in a blue subpixel and emits blue light. Alternatively, the light emitting layer 234 can be a white (W) light emitting layer that emits white light.

The light emitting layer 234 can include, but not limited to, an organic light emitting layer, or an inorganic light emitting layer, for example, a nano-sized material layer, a quantum dot layer, a micro LED light emitting layer, or a mini LED light emitting layer.

The light emitting layer 234 can include, but not limited to, an electron injection layer and a hole injection layer that inject electrons and holes into an emission material layer, and an electron transport layer, a hole blocking layer, an electron blocking layer, and a hole transport layer that transport the injected electrons and holes into the emission material layer.

The second electrode 236 can be positioned on the light emitting layer 234 and be formed of a transparent conductive material, such as ITO (Indium Tin Oxide) or IZO (Indium Zinc Oxide), or a thin metal that transmits visible light, but not limited thereto.

Furthermore, the organic light emitting element D can be configured in a tandem structure. The tandem structure can include multiple organic layers, and a charge generation layer can be included between the organic layers. The charge generation layer can serve to control charge balance between the plurality of organic layers, and can be configured with multiple layers including a first charge generation layer and a second charge generation layer. The charge generation layer can include an N-type charge generation layer and a P-type charge generation layer, and can be formed with an organic layer doped with an alkali metal, such as Li, Na, K, or Cs, or an alkaline earth metal, such as Mg, Sr, Ba, or Ra, but not limited thereto.

An encapsulation layer 280 can be formed on the second electrode 236 of the organic light emitting element D. In this regard, when the organic light emitting element D is exposed to moisture or oxygen, a pixel shrinkage phenomenon in which an emission region shrinks, or a defect such as a dark spot within the emission region can occur. Furthermore, moisture or oxygen oxidizes an electrode of metal. The encapsulation layer 280 can block penetration of moisture and oxygen from the outside and prevent defects in the organic light emitting element D and various electrodes.

The encapsulation layer 280 can be configured with a first encapsulation layer 282, a second encapsulation layer 284, and a third encapsulation layer 286, but not limited thereto and can be configured with two, four, or more layers.

The first encapsulation layer 282 and the third encapsulation layer 286 can each be formed in a single layer or multiple layers using an inorganic material such as SiOx, SiON, or SiNx, and can further include an organic material between the inorganic layers, but not limited thereto. The second encapsulation layer 284 can be formed of an organic insulating material such as acrylic resin, epoxy resin, polyimide, polyethylene, or silicon oxycarbon (SiOC), but not limited thereto. The third encapsulation layer 286 can be formed of a thin metal (e.g., face seal metal), but not limited thereto.

A touch member can be placed on the encapsulation layer 280. The touch member can be placed in a display region to detect a touch input. The touch member can detect an external touch information using a user's finger or a touch pen.

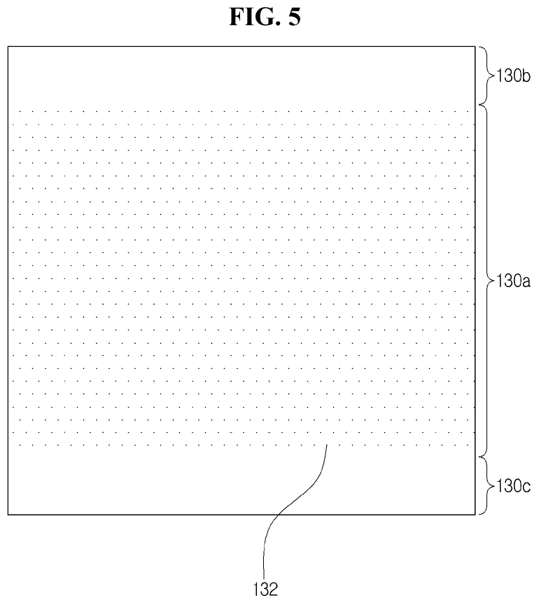

FIG. 5 is a plan view of a support member according to one or more embodiments of the present disclosure.

As illustrated in FIG. 5, the support member 130 includes a first support member 130a, a second support member 130b, and a third support member 130c. The first support member 130a can be a bending region, and the second support member 130b and the third support member 130c can be flat regions.

The first support member 130a can be a region where the display module 110 is wound around the guide member 150 when housed in the housing 120. The plurality of chamfers 132 can be formed at the lower surface of the first support member 130a.

The first support member 130a can correspond to the display region of the display panel PNL. The second support member 130b and the third support member 130c can correspond to a pad region or a peripheral region of the display panel PNL outside the display region.

In the slidable display apparatus 100 according to the present disclosure, one end of the display module 110 can be fixed to the guide member 150, and the other end of the display module 110 can protrude from the housing 120, or can be positioned at an outlet of the housing 120. Furthermore, in one end of the display module 110, various driving elements can be provided and a pad region to which a flexible printed circuit board is attached can be formed.

The second support member 130b and the third support member 130c can be a fixed region and a pad region where the display module 110 is fixed to the guide member 150.

The plurality of chamfers 132 can be formed at the rear surface of the first support member 130a. The chamfers 132 can provide bendability to the support member 130 made of a metal material, thereby allowing the support member 130 to be wound around the guide member 150. In the drawing, the chamfers 132 are formed in the first support member 130a, but the chamfers 132 can also be formed in the second support member 130b and/or the third support member 130c of the support member 130.

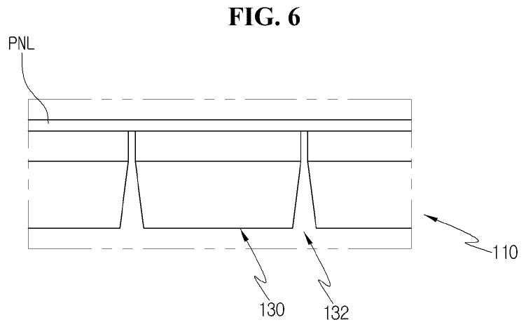

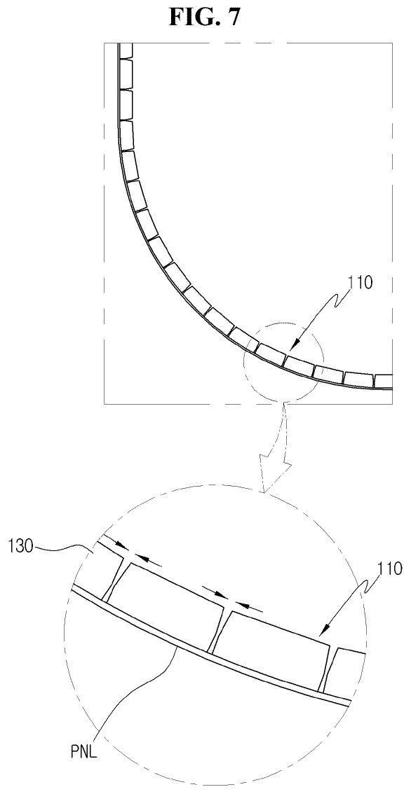

FIG. 6 is a view enlarging a part of a support member, and FIG. 7 is a view illustrating a support member wound around a guide member.

As illustrated in FIG. 6, the chamfers 132 can be formed to entirely penetrate the support member 130, and in this case, its width can decrease from one surface (a surface opposite to a surface which the display panel PNL is attached) to the other surface (the surface to which the display panel PNL is attached). For example, the chamfer 132 can be configured substantially in a trapezoidal shape, but not limited thereto.

As illustrated in FIG. 7, when the display module 110 is slid and accommodated in the housing 120, the support member 130 can be wound around the guide member 150. When the support member 130 is wound around the guide member 150, the support member 130 can be bent. At this time, as the width of the chamfer 132 decreases, the support member 130 can be bent at a certain curvature, and due to the trapezoidal shape of the chamfer 132, the support member 130 can be further bent at the same curvature as that of the guide member 150 and be wound around the guide member 150.

In other words, in the present disclosure, the support member 130 can be bent to a desired curvature by the width and shape of the chamfer 132. Therefore, by adjusting the width and shape of the chamfer 132, the curvature of the bendable support member 130 can be adjusted. In addition, by adjusting a spacing between the chamfers 132, the curvature of the bendable support member 130 can be adjusted.

As such, in the present disclosure, by adjusting the width, shape, and spacing of the chamfer 132 formed at the support member 130 in accordance with the curvature of the curved portion 151 of the guide member 150, the display module 110 can be wound around the guide member 150 and accommodated.

Meanwhile, since the display apparatus 100 according to one or more embodiments of the present disclosure can be applied to various electronic devices, the housing 120 in which the display module 110 is accommodated can be formed in various shapes depending on the shapes of the electronic devices. Accordingly, when the curved portion 151 in which the display module 110 is accommodated is formed in an elliptical cylindrical shape, the curvature of the curved portion 151 can vary depending on positions. In this case, the width, shape, and spacing of the chamfers 132 of the support member 130 can be set differently depending on the positions of the first support member 130a according to the curvature of the curved portion 151.

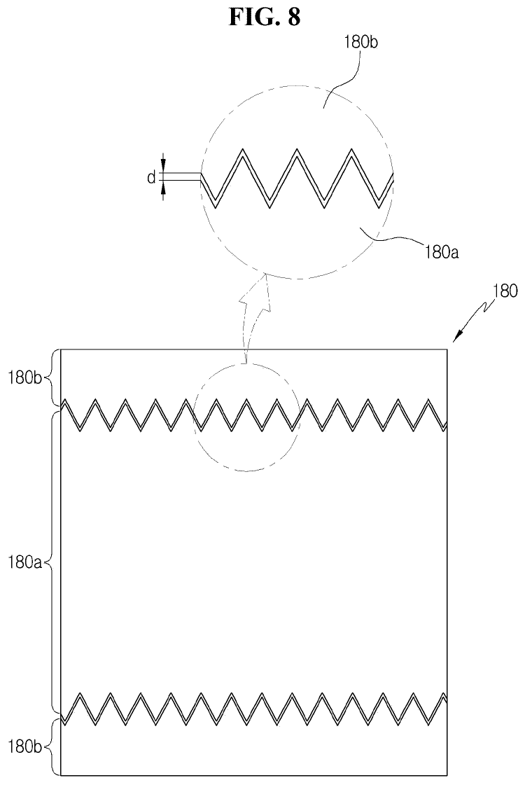

As illustrated in FIG. 8, the adhesive member 180 can include a first adhesive member 180a, a second adhesive member 180b, and a third adhesive member 180c. The first adhesive member 180a can be attached to the first support member 130a, and the second adhesive member 180b and the third adhesive member 180c can be attached to the second support member 130b and the third support member 130c, respectively.

In the present disclosure, by configuring moduli of the first, second, and third adhesive members 180a, 180b, and 180c differently, the adhesive member 180 can be prevented from being peeled off from the display panel PNL and/or the support member 130.

The first adhesive member 180a can be a region that is wound around the curved portion 151 of the guide member 150 in a state in which the first support member 130a are attached to the display region of the display panel PNL. The second adhesive member 180b and the third adhesive member 180c may not be regions to be wound but can be flat regions. Thus, when the adhesive member 180 is attached to the support member 130 and the display panel PNL and is wound around the curved portion 151 of the guide member 150, stress can be generated between the first adhesive member 180a, the second adhesive member 180b, and the third adhesive member 180c, and due to this difference in stress, a specific region, for example, the first adhesive member 180a, can be peeled off from the support member 130 and the display panel PNL.

However, in the present disclosure, the modulus of the first adhesive member 180a wound around the curved portion 151 of the guide member 150 can be set to be smaller than the moduli of the second adhesive member 180b and the third adhesive member 180c. Thus, when the adhesive member 180 is wound around the curved portion 151 of the guide member 150, the stress in this region can be minimized or at least reduced, thereby preventing the adhesive member 180 in this region from being peeled off from the display panel PNL and the support member 130. At this time, the modulus of the second adhesive member 180b and the modulus of the third adhesive member 180c can be the same, but not limited thereto.

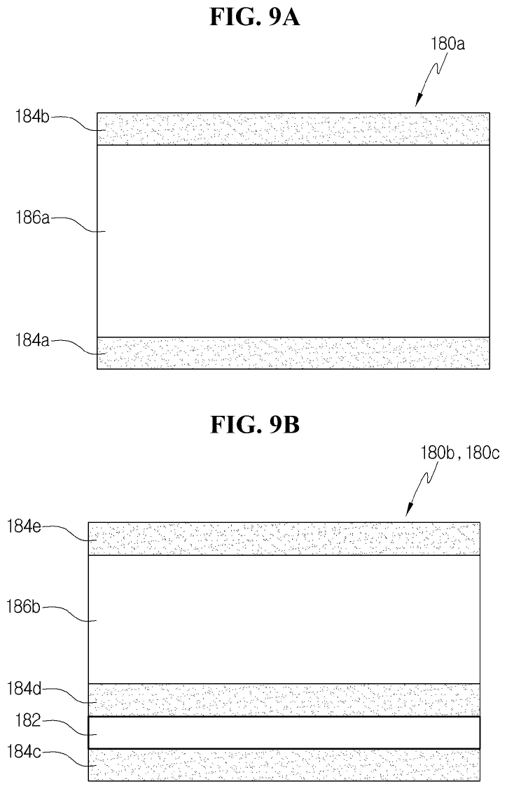

FIG. 9A is a cross-sectional view of a first adhesive member, and FIG. 9B is a cross-sectional view of second and third adhesive members.

As illustrated in FIG. 9A, the first adhesive member 180a can include a first foam member 186a and first and second adhesive layers 184a and 184b formed on lower and upper surfaces of the first foam member 186a, respectively.

The first foam member 186a can be formed of a resin such as a urethane-based resin or an acrylic-based resin, but not limited thereto. In this case, the first foam member 186a can be formed to a thickness of approximately 350 μm to 400 μm, but not limited thereto.

The first and second adhesive layers 184a and 184b can be formed of various adhesive materials. For example, the first and second adhesive layers 184a and 184b can be formed of an acrylic-based, silicone-based, or urethane-based adhesive material, but not limited thereto. The first and second adhesive layers 184a and 184b can be formed to a thickness of approximately 40 μm to 60 μm, but not limited thereto.

As illustrated in FIG. 9B, the second and third adhesive members 180b and 180c can each include a base 182, third and fourth adhesive layers 184c and 184d disposed on lower and upper surfaces of the base 182, respectively, a second foam member 186b disposed on an upper surface of the fourth adhesive layer 184d, and a fifth adhesive layer 184e disposed on an upper surface of the second foam member 186b.

The base 182 can be formed of a flexible plastic material, for example, polyethylene terephthalate, but not limited thereto. In this case, the base 182 can be formed to a thickness of 40 μm to 50 μm, but not limited thereto.

The second foam member 186b can be formed of a resin such as a urethane-based resin or an acrylic-based resin, but not limited thereto. In this case, the second foam member 186b can be formed to a thickness of approximately 250 μm to 350 μm, but not limited thereto.

The third to fifth adhesive layers 184c, 184d, and 184e can be formed of various adhesive materials. For example, the third to fifth adhesive layers 184c, 184d, and 184e can be formed of an acrylic-based, silicone-based, or urethane-based adhesive material, but not limited thereto. The third to fifth adhesive layers 184c, 184d, and 184e can be formed to a thickness of approximately 40 μm to 60 μm, but not limited thereto.

Comparing the first adhesive member 180a with the second and third adhesive members 180b and 180c, the first adhesive member 180a is not provided with the base 182, whereas the second and third adhesive members 180b and 180c are provided with the base 182. Depending on the presence or absence of the base 182, a difference in modulus can occur between the first adhesive member 180a and the second and third adhesive members 180b and 180c, and due to this difference in modulus, peeling due to stress difference does not occur when the display module 110 is wound around the guide member 150.

The first to third adhesive members 180a, 180b, and 180c can be attached to the display panel PNL and the support member 130 while being spaced apart from each other by a predetermined distance d. The separation distance d can be to prevent the first to third adhesive members 180a, 180b, and 180c from overlapping each other due to different moduli when attaching the first to third adhesive members 180a, 180b, and 180c separated from each other. The separation distance d can be determined according to the moduli of the first to third adhesive members 180a, 180b, and 180c.

The first to third adhesive members 180a, 180b, and 180c at boundaries between the first to third support members 130a, 130b, and 130c can be formed in a sawtooth shape rather than a straight line. Thus, local stress concentrated at the boundaries between the first to third support members 130a, 130b, and 130c can be dispersed, thereby preventing peeling of the adhesive member (180) at these boundaries.

The sawtooth shape of the first to third adhesive members 180a, 180b, and 180c at the boundaries can be triangular, but can also be formed in other shape.

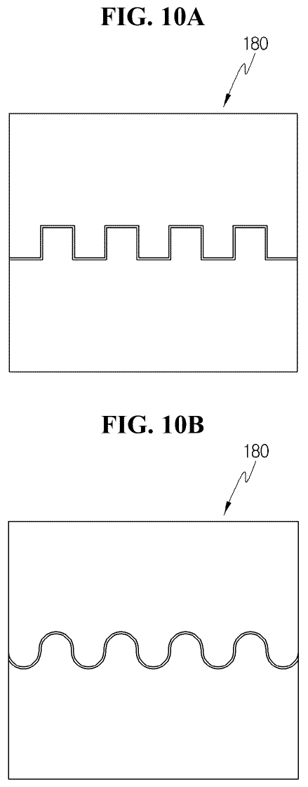

As illustrated in FIGS. 10A and 10B, the sawtooth shape can be rectangular or circular.

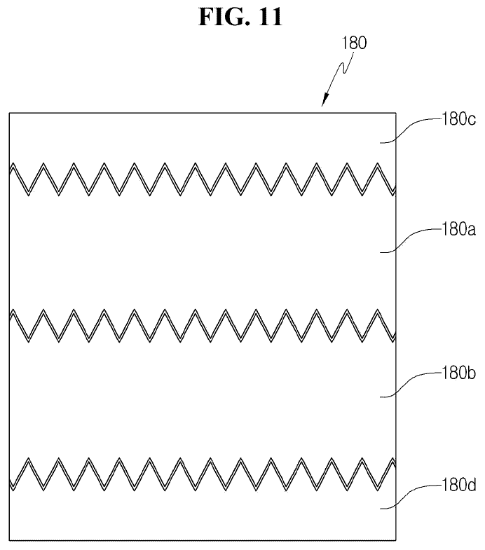

FIG. 11 is a view illustrating another structure of an adhesive member according to one or more embodiments of the present disclosure.

As illustrated in FIG. 11, the adhesive member 180 can include first, second, third, and fourth adhesive members 180a, 180b, 180c, and 180d.

Here, the first adhesive member 180a and the second adhesive member 180b can be regions that are wound around the curved portion 151 of the guide member 150, while the third adhesive member 180c and the fourth adhesive member 180d can flat regions, not regions to be wound.

In the adhesive member 180 of this structure, the regions that are wound around the curved portion 151 of the guide member 150 can be separated from each other, thereby dispersing stress that can occur in these regions i.e., curved regions, thereby preventing the adhesive member 180 from being peeled off.

As described above, in the present disclosure, by varying the modulus of the adhesive member that attaches the support member to the display panel, stress in the region wound in a curved shape can be minimized or at least reduced, thereby preventing the support member in the wound region from being peeled off from the display panel.

Furthermore, by forming the boundaries of the adhesive members of different regions into a sawtooth shape, local stress concentrated at the boundaries between the regions can be dispersed, thereby more effectively preventing peeling of the adhesive material at the boundary regions.

Furthermore, by preventing the peeling of the adhesive member, disposal of the peeled defective adhesive member can be prevented. Thus, environmental friendliness is made possible by preventing the disposal of hazardous substances.

The detailed description above exemplifies the slidable display apparatus, but the present disclosure is not limited to any specific display apparatus. For example, the present disclosure can be applied to various display apparatuses, such as a foldable display apparatus, a bendable display apparatus, an extendable display apparatus, and a flexible display apparatus. When applied to such the display apparatuses, the modulus of the adhesive member in a deformed region, for example, a folding region, a bending region, an extending region, or a flexing region, can be set to be smaller than the modulus of the adhesive member in a non-deformed region, thereby preventing peeling of the adhesive member due to stress.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus, comprising:
a display panel including a first region where an image is displayed, a second region, and a third region, wherein the first region is deformable, and wherein the second region and the third region are positioned outside the first region and are not deformable;
a support member that supports the display panel; and
an adhesive member that attaches the support member to the display panel,
wherein the adhesive member includes a first adhesive member corresponding to the first region of the display panel, a second adhesive member corresponding to the second region of the display panel, and a third adhesive member corresponding to the third region of the display panel, and
wherein a modulus of the first adhesive member is smaller than a modulus of the second adhesive member and a modulus of the third adhesive member.

2. The display apparatus of claim 1, wherein the first adhesive member, the second adhesive member, and the third adhesive member are configured with double-sided tapes.

3. The display apparatus of claim 2, wherein boundary surfaces between the first adhesive member, the second adhesive member, and the third adhesive member are formed in a sawtooth shape.

4. The display apparatus of claim 3, wherein the sawtooth shape includes one of a triangular shape, a rectangular shape, and a circular shape.

5. The display apparatus of claim 1, wherein the first adhesive member includes:
a first foam member;
a first adhesive layer formed on a lower surface of the first foam member; and
a second adhesive layer formed on an upper surface of the first foam member that is opposite to the lower surface of the first foam member.

6. The display apparatus of claim 5, wherein the first adhesive member includes two regions separated from each other.

7. The display apparatus of claim 1, wherein each of the second adhesive member and the third adhesive member includes:
a base;
a third adhesive layer disposed on a lower surface of the base;
a fourth adhesive layer disposed on an upper surface of the base that is opposite to the lower surface of the base;
a second foam member disposed on the fourth adhesive layer; and
a fifth adhesive layer disposed on the second foam member.

8. The display apparatus of claim 5, wherein the first foam member includes a resin.

9. The display apparatus of claim 7, wherein the second foam member includes a resin.

10. The display apparatus of claim 7, wherein the base includes a plastic material with flexibility.

11. The display apparatus of claim 1, wherein the support member includes a metal material.

12. The display apparatus of claim 11, wherein the support member includes:
a first support member attached to the first adhesive member at a first surface of the first adhesive member;
a second support member attached to the second adhesive member at a first surface of the second adhesive member; and
a third support member attached to the third adhesive member at a first surface of the third adhesive member.

13. The display apparatus of claim 12, wherein a plurality of chamfers are formed at a second surface of the first support member opposite to the first surface of the first support member.

14. The display apparatus of claim 13, wherein a first chamfer of the plurality of chamfers is formed in a trapezoidal shape and penetrates the first support member.

15. The display apparatus of claim 13, wherein the display panel is a slidable display panel.

16. The display apparatus of claim 15, further comprising:
a housing for accommodating the display panel; and
a guide member guiding the display panel into the housing and winding the display panel.

17. The display apparatus of claim 16, wherein the guide member is formed in a cylindrical shape, and wherein the guide member includes a curved portion around which the display panel is wound.

18. The display apparatus of claim 17, wherein a width of the plurality of chamfers and a spacing of the plurality of chamfers are determined according to a curvature of the curved portion.
19, The display apparatus of claim 1, wherein the modulus of the second adhesive member and the modulus of the third adhesive member are same.
